(19) United States
(12) Patent Application Publication
(10) Pub. No.: US 2025/0279394 A1
(43) Pub. Date: Sep. 4, 2025

(54) BRIDGE CHIP, FAN-OUT PACKAGE STRUCTURE AND CORRESPONDING PACKAGING METHOD

(71) Applicant: STATS CHIPPAC SEMICONDUCTOR (JIANGYIN) CO., LTD., JIANGSU (CN)

(72) Inventors: Zelong Yu, Jiangsu (CN); Shuai Yang, Jiangsu (CN); Zhenbin Hu, Jiangsu (CN); Jian Xu, Jiangsu (CN)

(73) Assignee: STATS CHIPPAC SEMICONDUCTOR (JIANGYIN) CO., LTD., JIANGSU (CN)

(21) Appl. No.: 18/594,005

(22) Filed: Mar. 4, 2024

(30) Foreign Application Priority Data
Jan. 4, 2023 (CN) 202310007343.X

(51) Int. Cl. H01L 25/065; H01L 21/56; H01L 23/00; H01L 23/31; H01L 23/36; H01L 23/538; H01L 25/00

(52) U.S. Cl. CPC H01L 25/0652; H01L 21/568; H01L 23/3107; H01L 23/36; H01L 23/5383; H01L 24/16; H01L 24/32; H01L 24/45; H01L 24/48; H01L 24/73; H01L 24/92; H01L 25/50; H01L 2224/16227; H01L 2224/32225; H01L 2224/45144; H01L 2224/45147; H01L 2224/48227; H01L 2224/73204; H01L 2224/73257; H01L 2224/73265; H01L 2224/92127; H01L 2224/92227; H01L 2224/92247; H01L 2225/06572

(57) ABSTRACT

The present invention relates to the technical field of chip packaging, and discloses a bridge chip, a fan-out package structure and a corresponding packaging method, wherein a top surface of the bridge chip is provided with a plurality of first pads and a chip connecting structure, the plurality of first pads are separately configured to connect a lead, the lead is configured to electrically connect the top surface of the bridge chip and a first metal wire layer that is connected to a bottom surface of the bridge chip, and the chip connecting structure is configured to bridge at least two chips. The present invention conducts the bridge chip by a lead bonding technology, has a stable and mature process, fully utilizes an internal space of a fan-out package body without increasing a thickness and a volume of the package body, and thereby maximizing the chip function.

### CROSS-REFERENCE TO RELATED APPLICATION

This application claims the priority benefit of China application serial no. 202310007343.X, filed on Jan. 4, 2023. The entirety of the above-mentioned patent application is hereby incorporated by reference herein and made a part of this specification.

### TECHNICAL FIELD

The present invention relates to the technical field of chip packaging, and specifically to a bridge chip, a fan-out package structure and a corresponding packaging method.

### BACKGROUND

In the fan-out high-density integrated package, a common method for interconnecting chips is to achieve an effective connection through a bottom bridge chip. Specifically, as shown in FIG. 1, a conventional chip package structure comprises a substrate 100 and a chip structure 200 located on a surface of the substrate; FIG. 2 shows a schematic diagram of the chip structure with a bridge chip, it can be seen that in the chip structure 200, the functional surfaces of the bridge chip 40 are electrically connected to a first chip 61 and a second chip 62, respectively, the non-functional surfaces of the bridge chip are connected to a passivation layer (PI) through a wafer attach film 47, and the solder balls at corresponding positions below the bridge chip, that is, the solder balls inside a dashed frame 11 are all dummy solder balls.

In the conventional technology, in order to achieve uniformity of solder ball distribution, solder balls are required to be arranged at corresponding positions below a bridge chip. However, since only one side of the bridge chip at the bottom is a functional surface at present, and a non-functional surface at the other side is bonded to a passivation layer (PI) through a wafer attach film to achieve the effect of fixing the bridge chip, the solder balls below the bridge chip are not provided with circuits to be connected and thus are all dummy solder balls without actual functions, and the dummy solder balls occupy a large area of the chip; consequently, the area of an actual effective area is greatly reduced.

### SUMMARY

An objective of the present invention is to overcome low effectiveness of the existing chip package structure with a bridge chip, and to provide a bridge chip, a fan-out package structure and a corresponding packaging method.

In order to achieve the above objective, the present invention provides a bridge chip, wherein a top surface of the bridge chip is provided with a plurality of first pads and a chip connecting structure, the plurality of first pads are separately configured to connect a lead, the lead is configured to electrically connect the top surface of the bridge chip and a first metal wire layer that is connected to a bottom surface of the bridge chip, and the chip connecting structure is configured to bridge at least two chips.

In an implementation, the bottom surface of the bridge chip is configured to electrically connect to the first metal wire layer.

In an implementation, the bottom surface of the bridge chip is configured to be bonded to a first surface of the first metal wire layer by a plurality of bumps.

In an implementation, the top surface and the bottom surface of the bridge chip each have an independent device structure, and the top surface and the bottom surface of the bridge chip are electrically connected through the lead, the first metal wire layer and the bump.

In an implementation, the plurality of first pads are separately arranged on the top surface that is of the bridge chip and that is close to an outer edge.

In an implementation, the top surface of the bridge chip further has other device structures that are not limited to the function of interconnecting the chips.

An embodiment of the present invention further provides a fan-out package structure, comprising: a first metal wire layer, a bridge chip molding layer located on a first surface of the first metal wire layer, and a chip structure molding layer that is located on a surface of the bridge chip molding layer and that is electrically connected to the surface of the bridge chip molding layer;
wherein the bridge chip molding layer comprises a bridge chip, the first surface of the first metal wire layer is provided with a plurality of second pads corresponding to first pads, and the first pads and the corresponding second pads are connected through leads, so that a top surface of the bridge chip is electrically connected to the first metal wire layer.

In an implementation, a second metal wire layer is further provided between the bridge chip molding layer and the chip structure molding layer, the second metal wire layer is located on the surface of the bridge chip molding layer and electrically connected to a chip connecting structure of a bridge chip in the bridge chip molding layer, the chip structure molding layer is located on a surface of the second metal wire layer, and at least two chips of the chip structure molding layer are electrically connected to the second metal wire layer.

In an implementation, when a bottom surface of the bridge chip is bonded to a first surface of the first metal wire layer by a plurality of bumps, a curing adhesive is filled around the plurality of bumps between the bottom surface of the bridge chip and the first metal wire layer.

In an implementation, the lead is a copper wire or a gold wire.

In an implementation, the plurality of second pads are separately arranged around the bridge chip and corresponding to the first pads.

In an implementation, the bridge chip molding layer further comprises a conductive metal pillar and a molding compound encapsulating the bridge chip, the conductive metal pillar and the lead, the first metal wire layer is electrically connected to the second metal wire layer through the conductive metal pillar, and the chip connecting structure on the top surface of the bridge chip is electrically connected to the second metal wire layer through a plurality of bumps.

In an implementation, the chip structure molding layer comprises a first chip and a second chip separately electrically connected to the second metal wire layer and a molding compound encapsulating the first chip and the second chip, and the bridge chip is electrically connected to the first chip and the second chip separately through the second metal wire layer.

In an implementation, the fan-out package structure further comprises a substrate and a heat dissipating lid, wherein the substrate is electrically connected to a second surface of the first metal wire layer.

In an implementation, the second surface of the first metal wire layer has a solder ball, a part of the solder ball located at a corresponding position of the bridge chip is electrically connected to the second pad, and the top surface of the bridge chip is electrically connected to the substrate through the lead, the second pad, and the part of the solder ball located at a corresponding position of the bridge chip.

An embodiment of the present invention further provides a manufacturing method for a fan-out package structure, which comprises the following steps:
providing a temporary carrier board, forming a plated layer on a surface of the temporary carrier board, and forming a first metal wire layer on a surface of the plated layer;
forming a bridge chip molding layer on a first surface of the first metal wire layer, wherein the bridge chip molding layer comprises a bridge chip, the bridge chip is located on the first surface of the first metal wire layer, a top surface of the bridge chip is provided with a plurality of first pads, the first surface of the first metal wire layer is provided with a plurality of second pads corresponding to first pads, and the first pads and the corresponding second pads are connected through leads, so that the top surface of the bridge chip is electrically connected to the first metal wire layer;
forming a chip structure molding layer on a surface of the bridge chip molding layer, wherein the chip structure molding layer is electrically connected to the bridge chip molding layer; and
removing the temporary carrier board and the plated layer.

In an implementation, after removing the temporary carrier board and the plated layer, the method further comprises the following steps: mounting the structure formed above to a substrate, and additionally mounting a heat dissipating lid.

In an implementation, the step of mounting the structure formed above to a substrate specifically comprises: after removing the temporary carrier board and the plated layer, forming a solder ball on a second surface of the first metal wire layer, bonding the first metal wire layer on a surface of the substrate through the solder ball, electrically connecting the first metal wire layer and the surface of the substrate through the solder ball, and electrically connecting the top surface of the bridge chip and the substrate through the lead, the second pad, the first metal wire layer and the solder ball.

In an implementation, a chip structure molding layer is formed on the surface of the bridge chip molding layer, and the step of electrically connecting the chip structure molding layer and the bridge chip molding layer specifically comprises:
forming a second metal wire layer on the surface of the bridge chip molding layer, wherein a bridge chip of the bridge chip molding layer is electrically connected to the second metal wire layer; and
forming a chip structure molding layer on the surface of the second metal wire layer, wherein at least two chips of the chip structure molding layer are electrically connected to the second metal wire layer.

In an implementation, the plurality of first pads are separately arranged on the top surface that is of the bridge chip and that is close to an outer edge, and the plurality of second pads are separately arranged around the bridge chip and corresponding to the first pads.

In an implementation, the step of forming a bridge chip molding layer specifically comprises:
providing a bridge chip, wherein the bridge chip comprises a bottom surface and an opposite top surface, the bottom surface of the bridge chip is provided with a plurality of bumps, and the top surface of the bridge chip is provided with a plurality of first pads;
bonding the bridge chip on the first surface of the first metal wire layer through the plurality of bumps on the bottom surface, and forming a conductive metal pillar on the first surface of the first metal wire layer;
filling around the bumps between the bottom surface of the bridge chip and the first metal wire layer by using a filler, and connecting the first pad and the corresponding second pad through a lead, so that the top surface of the bridge chip is electrically connected to the first metal wire layer; and
providing a molding compound to mold the bridge chip, the conductive metal pillar and the lead to form the bridge chip molding layer.

The beneficial effects of the present invention are as follows.

The present invention discloses a bridge chip, wherein a top surface of the bridge chip is provided with a plurality of first pads and a chip connecting structure, the plurality of first pads are separately configured to connect a lead, the lead is configured to electrically connect the top surface of the bridge chip with a first metal wire layer that is connected to a bottom surface of the bridge chip, and the chip connecting structure is configured to bridge at least two chips.

According to the present invention, the bridge chip is conducted with the first metal wire layer through the lead bonding technology, the process is stable and mature, the bridge chip not only plays a role of interconnecting the chips above, but also can be conducted with the substrate through the first metal wire layer and the solder ball, so that an invalid solder ball area below an original bridge chip is changed into a functional solder ball area, all areas of the fan-out packaging body are effectively utilized, and the efficiency of the fan-out package body is greatly enhanced.

The present invention replaces a wafer attach film material by filling a curing adhesive around the bumps at the bottom of the bridge chip, such that the chip structure is firmer.

Since the bridge chip is not only connected to the first chip and the second chip, but also electrically connected to the substrate through the lead and the first metal wire layer, the bridge chip and the substrate can be further designed, so that the bridge chip can be designed to have an independent circuit structure to achieve other unique functions, which provides a basis for the expanded design of the bridge chip; moreover, since the bridge chip has a large redundant space in the bridge chip molding layer, a size of a bridge chip applicable to the present invention can be far greater than that of a bridge chip in the conventional technology, which is beneficial to improving the design integration degree of the chip.

### BRIEF DESCRIPTION OF THE DRAWINGS

FIG. 1 is a schematic diagram of an existing package structure;

FIG. 2 is a schematic diagram of the connection of a bridge chip in an existing package structure; and

FIG. 3 to FIG. 14 are schematic diagrams of a process of forming a fan-out package structure comprising a bridge chip according to an embodiment of the present invention.

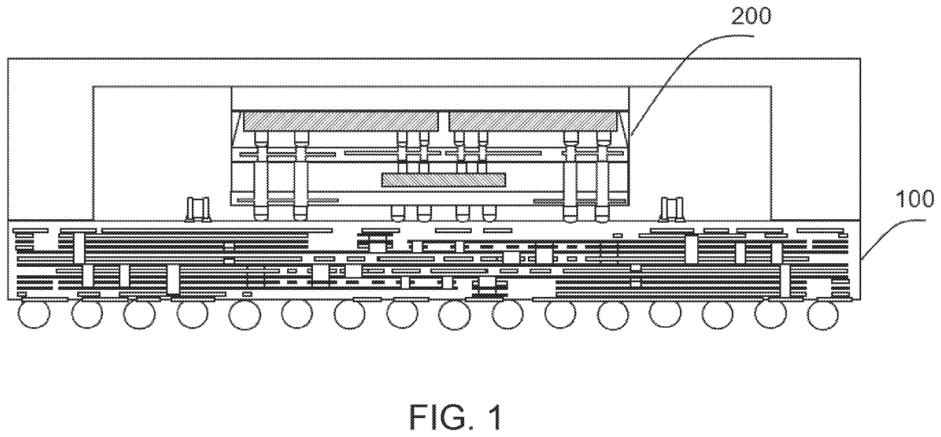

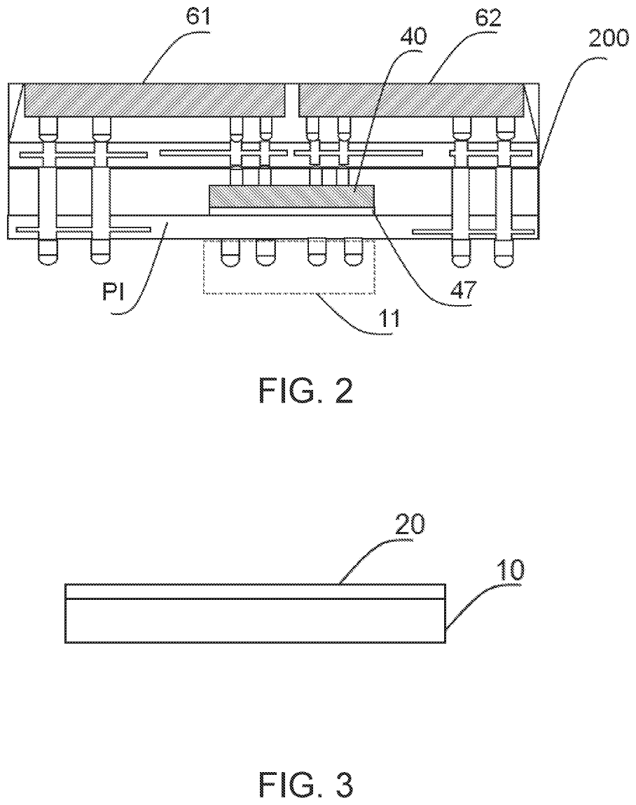

### DETAILED DESCRIPTION

The following clearly and completely describes the technical solutions in embodiments of the present invention with reference to the accompanying drawings in embodiments of the present invention. It is clear that the described embodiments are merely a part rather than all of embodiments of the present invention. Based on the embodiments of the present invention, all other embodiments obtained by those of ordinary skill in the art without creative effort fall within the protection scope of the present invention.

This embodiment provides a technical solution: a bridge chip, wherein a top surface of the bridge chip is provided with a plurality of first pads and a chip connecting structure, the plurality of first pads are separately configured to connect a lead, the lead is configured to electrically connect the top surface of the bridge chip with a first metal wire layer that is connected to a bottom surface of the bridge chip, and the chip connecting structure is configured to bridge at least two chips.

The bottom surface of the bridge chip is a surface that is of the bridge chip and that faces the first metal wire layer, and the top surface of the bridge chip is a surface opposite to the bottom surface facing the first metal wire layer.

The bottom surface of the bridge chip is configured to electrically connect to the first metal wire layer.

Specifically, the bottom surface of the bridge chip is configured to be bonded to a first surface of the first metal wire layer by a plurality of bumps.

The plurality of first pads are separately arranged on the top surface that is of the bridge chip and that is close to an outer edge.

In other embodiments, the top surface and the bottom surface of the bridge chip each have an independent device structure, and the top surface and the bottom surface of the bridge chip are electrically connected through the first metal wire layer and the lead.

In other embodiments, the top surface of the bridge chip further has other device structures not limited to the function of interconnecting the chips in the chip structure molding layer, and the bridge chip may also have an independent circuit structure to implement other unique functions, and is connected to the first metal wire layer through a lead, so as to provide a basis for the extended design of the bridge chip. The other device structure may be, for example, a MOS device, a passive device or the like, and the other unique function may be, for example, testing or other functions.

Correspondingly, this embodiment further provides a fan-out package structure, comprising: a first metal wire layer, a bridge chip molding layer located on a first surface of the first metal wire layer, and a chip structure molding layer that is located on a surface of the bridge chip molding layer and that is electrically connected to the surface of the bridge chip molding layer;
wherein the bridge chip molding layer comprises a bridge chip, the first surface of the first metal wire layer is provided with a plurality of second pads corresponding to first pads, and the first pads and the corresponding second pads are connected through leads, so that a top surface of the bridge chip is electrically connected to the first metal wire layer.

Further, a second metal wire layer is further provided between the bridge chip molding layer and the chip structure molding layer, the second metal wire layer is located on the surface of the bridge chip molding layer and electrically connected to a chip connecting structure of a bridge chip in the bridge chip molding layer, the chip structure molding layer is located on a surface of the second metal wire layer, and at least two chips of the chip structure molding layer are electrically connected to the second metal wire layer.

In other embodiments, the bridge chip molding layer may also be directly formed on the surface of the bridge chip molding layer, and the bridge chip is directly connected to at least two chips in the chip structure molding layer through the chip connecting structure.

In this embodiment, the bottom surface of the bridge chip is electrically connected to the first metal wire layer.

Further, in this embodiment, when a bottom surface of the bridge chip is bonded to a first surface of the first metal wire layer by a plurality of bumps, a curing adhesive is filled around the plurality of bumps between the bottom surface of the bridge chip and the first metal wire layer, so that the chip structure is firmer. The bump can be a conductive adhesive bump, a cylindrical bump, a micro bump and the like.

Since the bridge chip is not only connected to the first chip and the second chip through the second metal wire layer, but also electrically connected to the substrate through the lead and the first metal wire layer, the bridge chip and the substrate can be further designed, so that the bridge chip can be designed to have an independent circuit structure to achieve other unique functions, which provides a basis for the expanded design of the bridge chip; moreover, since the bridge chip has a large redundant space in the bridge chip molding layer, a size of a bridge chip applicable to the present invention can be far greater than that of a bridge chip in the conventional technology, which is beneficial to improving the design integration degree of the chip.

In other embodiments, when the bridge chip is a double-sided chip, that is, a top surface and a bottom surface of the bridge chip both have functional areas and devices, the top surface is electrically connected to a first metal wire layer and a substrate through the first pad, the lead and the second pad, the bottom surface is electrically connected to the first metal wire layer and the substrate through the bump on the bottom surface, and the top surface and the bottom surface can be electrically connected through the lead and the first metal wire layer, so that the performance of the chip is maximized.

In another implementation, the top surface and the bottom surface of the bridge chip may also be electrically connected by a through-silicon via (TSV).

In addition, in this embodiment, the plurality of first pads are separately arranged on the top surface that is of the bridge chip and that is close to an outer edge, and the plurality of second pads are separately arranged around the bridge chip and corresponding to the first pads; and a number of the first pads and a number of the second pads are determined according to actual requirements of products.

The bridge chip molding layer further comprises a conductive metal pillar and a molding compound encapsulating the bridge chip, the conductive metal pillar and the lead, the first metal wire layer is electrically connected to the second metal wire layer through the conductive metal pillar, and the top surface of the bridge chip is electrically connected to the second metal wire layer through a plurality of bumps.

The chip structure molding layer comprises a first chip and a second chip separately electrically connected to the second metal wire layer and a molding compound encapsulating the first chip and the second chip, and the bridge chip is electrically connected to the first chip and the second chip separately through the second metal wire layer.

The lead is a copper wire, a gold wire or other conductive metal wires, and the conductive metal pillar may be a copper pillar or the like.

Further, the fan-out package structure of this embodiment further comprises a substrate, and the substrate is electrically connected to a second surface of the first metal wire layer.

The second surface of the first metal wire layer is provided with solder balls, a part of the solder balls located at corresponding positions of the bridge chip are electrically connected to the second pad, the first metal wire layer is electrically connected to a surface of the substrate through the solder balls, and the top surface of the bridge chip is electrically connected to the substrate through the part of the solder balls positioned at the corresponding position of the bridge chip; therefore, the part of the solder balls positioned at the corresponding positions of the bridge chips are utilized instead of dummy solder balls, so that an invalid area below an original bridge chip is changed into a functional area, the solder balls, the metal wire layer and the substrate below the bridge chip are effectively utilized, all areas of the fan-out package body are effectively utilized, and the efficiency of the fan-out package body is greatly enhanced.

Based on the same inventive concept, an embodiment of the present invention further provides a manufacturing method for a fan-out package structure, which comprises the following steps:
providing a temporary carrier board, forming a plated layer on a surface of the temporary carrier board, and forming a first metal wire layer on a surface of the plated layer;
forming a bridge chip molding layer on a first surface of the first metal wire layer, wherein the bridge chip is located on the first surface of the first metal wire layer, a top surface of the bridge chip is provided with a plurality of first pads, the first surface of the first metal wire layer is provided with a plurality of second pads corresponding to first pads, and the first pads and the corresponding second pads are connected through leads, so that the top surface of the bridge chip is electrically connected to the first metal wire layer;
forming a chip structure molding layer on a surface of the bridge chip molding layer, wherein the chip structure molding layer is electrically connected to the bridge chip molding layer; and
removing the temporary carrier board and the plated layer.

Further, after removing the temporary carrier board and the plated layer, the method further comprises the following steps: mounting the structure formed above to a substrate, and additionally mounting a heat dissipating lid.

The plurality of first pads are separately arranged on the top surface that is of the bridge chip and that is close to an outer edge, and the plurality of second pads are separately arranged around the bridge chip and corresponding to the first pads.

A chip structure molding layer is formed on the surface of the bridge chip molding layer, and the step of electrically connecting the chip structure molding layer and the bridge chip molding layer specifically comprises:
forming a second metal wire layer on the surface of the bridge chip molding layer, wherein the bridge chip molding layer is electrically connected to the second metal wire layer; and
forming a chip structure molding layer on the surface of the second metal wire layer, wherein the chip structure molding layer is electrically connected to the second metal wire layer.

In this embodiment, the step of forming a bridge chip molding layer specifically comprises:
providing a bridge chip, wherein the bridge chip comprises a bottom surface and an opposite top surface, the bottom surface and the top surface of the bridge chip are provided with a plurality of bumps, the top surface of the bridge chip is further provided with a plurality of first pads, and the first pads are located at areas around the bumps;
bonding the bridge chip on the first surface of the first metal wire layer through a plurality of bumps on the bottom surface;
filling around the bumps between the bottom surface of the bridge chip and the first metal wire layer by using a filler, and connecting the first pad and the corresponding second pad through a lead, so that the top surface of the bridge chip is electrically connected to the first metal wire layer; and
providing a molding compound to mold the bridge chip, the conductive metal pillar and the lead to form the bridge chip molding layer.

The filler is a curing adhesive.

In this embodiment, the step of mounting the structure formed above to a substrate specifically comprises: after removing the temporary carrier board and the plated layer, forming a solder ball at a bottom of the first metal wire layer, bonding the first metal wire layer on the surface of the substrate through the solder ball, electrically connecting the first metal wire layer and the surface of the substrate through the solder ball, and electrically connecting the top surface of the bridge chip and the substrate through a part of the solder balls at the corresponding positions of the bridge chip.

Specifically, in this embodiment, FIG. 3 to FIG. 14 are schematic diagrams of a process of a manufacturing method for the fan-out package structure comprising the bridge chip of this embodiment;
firstly, as shown in FIG. 3, a temporary carrier board 10 is provided, and a plated layer 20 on a surface of the temporary carrier board 10 is formed; wherein, the temporary carrier board can be a glass sheet or a metal plate.

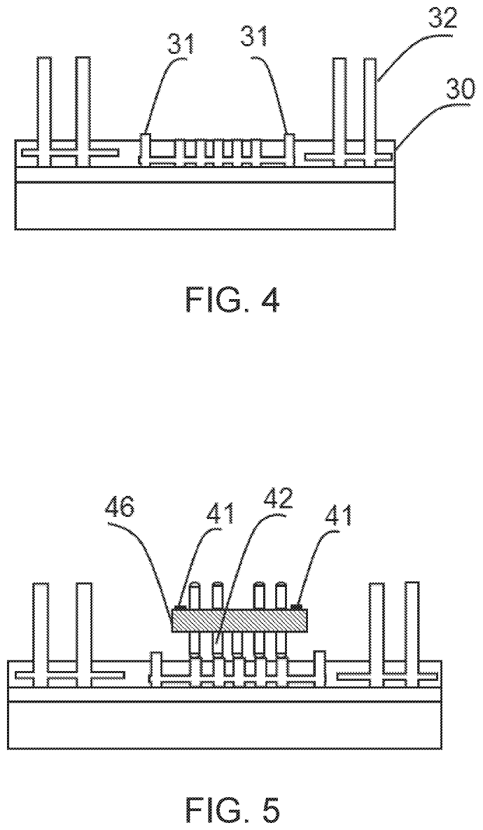

As shown in FIG. 4, a first metal wire layer 30 as well as a plurality of second pads 31 and a conductive metal pillar 32 that are located on the first surface of the first metal wire layer are formed on the surface of the plated layer 20, and the plurality of second pads 31 are separately located around the bridge chip after subsequent bonding.

As shown in FIG. 5, the bridge chip 46 is then bonded on the surface of the first metal wire layer 30, wherein the bottom surface and the corresponding top surface of the bridge chip are provided with a plurality of bumps 42, and the top surface of the bridge chip is further provided with a plurality of first pads 41 corresponding to the second pads; specifically, the bridge chip 46 is bonded on the surface of the first metal wire layer 30 through a plurality of bumps 42 on the bottom surface, and the plurality of first pads 41 are separately arranged on the top surface that is of the bridge chip and that is close to an outer edge.

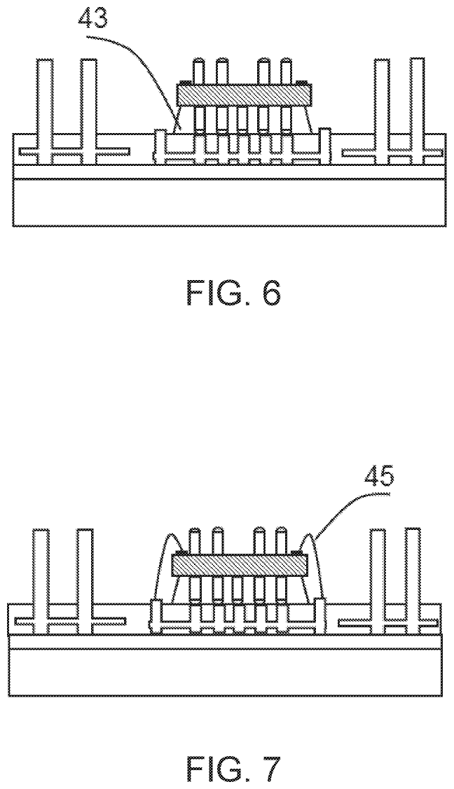

As shown in FIG. 6, a filler 43 is used to fill around the bumps between the bottom surface of the bridge chip 46 and the first metal wire layer 30; wherein the filler is a curing adhesive, which brings a firmer effect.

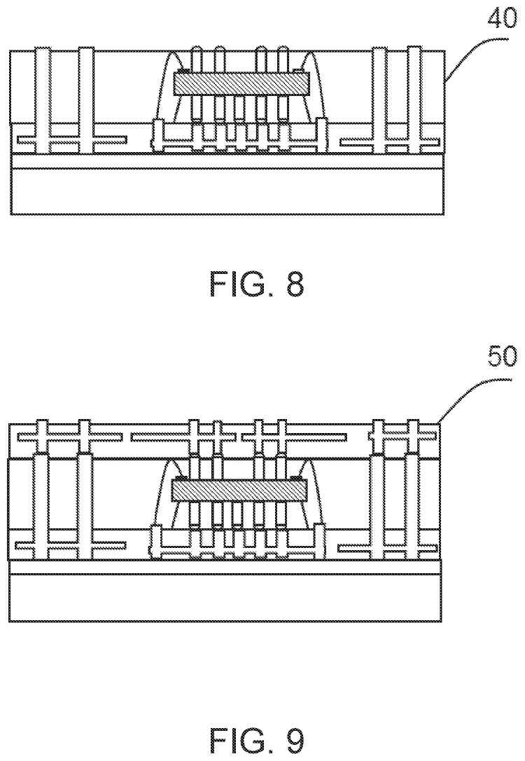

As shown in FIG. 7, the first pad and the corresponding second pad are connected by a lead 45, so that the top surface of the bridge chip is electrically connected to the first metal wire layer by the lead, and as shown in FIG. 8, a molding compound is provided to mold the bridge chip, the conductive metal pillar and the lead, thereby forming a bridge chip molding layer 40.

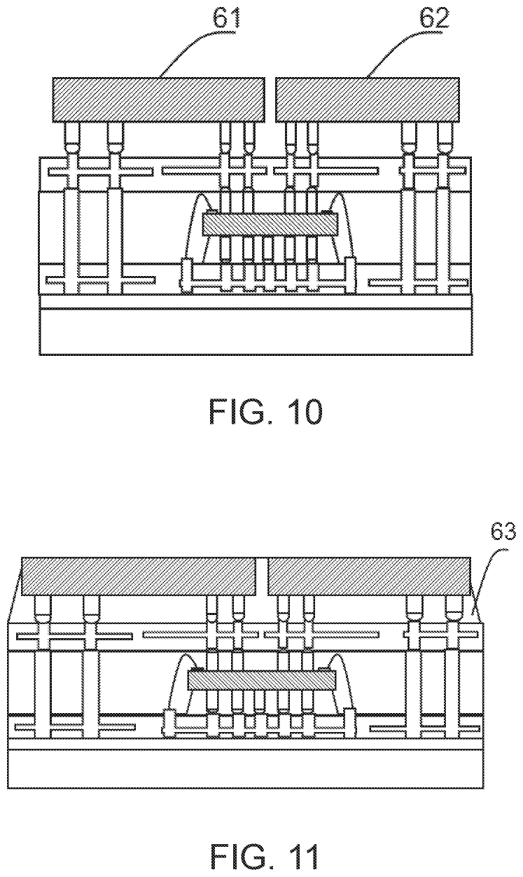

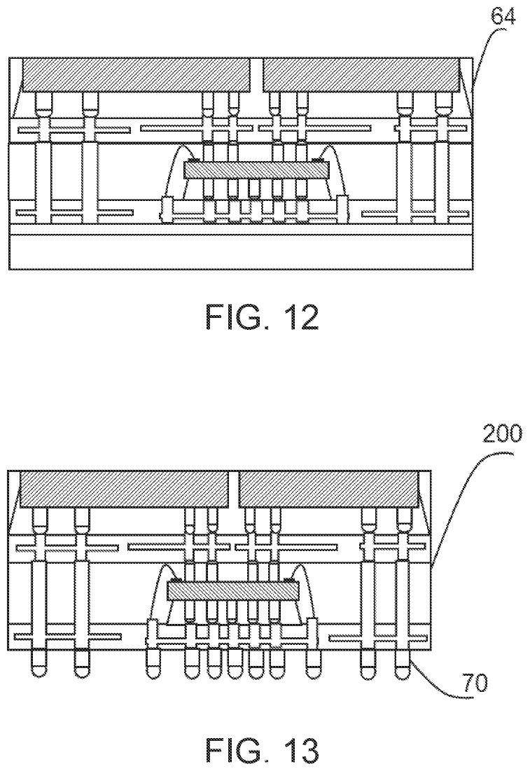

Next, as shown in FIG. 9, a second metal wire layer 50 is formed on a surface of the bridge chip molding layer 40, so that the bridge chip is electrically connected to the second metal wire layer through the bumps on the top surface, and the first metal wire layer is electrically connected to the second metal wire layer through the conductive metal pillar; as shown in FIG. 10, a first chip 61 and a second chip 62 are arranged on the surface of the second metal wire layer, so that the first chip and the second chip are electrically connected through the second metal wire layer and the bridge chip; as shown in FIG. 11, a filler 63 is used to fill the bottom of the chip, that is, around the bumps between the chips and between the chip and the second metal wire layer; and as shown in FIG. 12, a molding compound 64 is used to mold the chip, so as to form a chip structure molding layer.

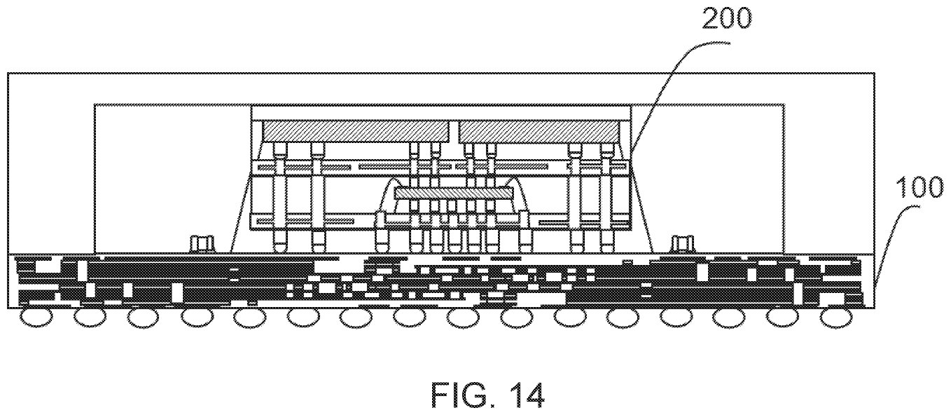

As shown in FIG. 13, the temporary carrier and the plated layer are removed, and a solder ball 70 is provided on the first metal wire layer and on the other side surface opposite to a side surface on which the bridge chip is provided; and as shown in FIG. 14, the chip structure 200 formed above is bonded to the substrate 100 and a heat dissipating lid is attached, and then the subsequent molding is performed.

The bridge chip provided by the embodiment of the present invention not only plays a role of interconnecting the chips above, but also can be conducted with the substrate through the lead, the first metal wire layer and the solder ball, so that an invalid solder ball area below an original bridge chip is changed into a functional solder ball area, all areas of the fan-out packaging body are effectively utilized, and the efficiency of the fan-out package body is greatly enhanced.

According to the embodiment of the present invention, the curing adhesive is filled around the bumps on the bottom, that is, the bottom surface of the bridge chip, to replace a wafer attach film material, so that the chip structure is firmer.

The embodiment of the present invention conducts the bridge chip by a lead bonding technology, has a stable and mature process, fully utilizes an internal space of the fan-out package body without increasing a thickness and a volume of the package body, and thereby maximizing the chip function; in addition, the cost is lower using a lead binding technology.

The present invention has a lower cost and a more mature process by using a lead bonding technology, and can achieve information intercommunication only by utilizing a small area at an edge of the bridge chip, thereby ensuring that the bridge chip can be utilized to the maximum extent on the premise of simpler process and thus improving the effectiveness of the bridge chip.

Specifically, the manufacturing method for the fan-out package structure of this embodiment specifically comprises:
providing a temporary carrier board, and forming a plated layer on a surface of the temporary carrier board;
forming a first metal wire layer on a surface of the plated layer, and forming a plurality of second pads and a conductive metal pillar that are located on a first surface of the first metal wire layer; wherein the plurality of second pads are separately located around the bridge chip that is subsequently bonded on the first surface of the first metal wire layer;
providing a bridge chip, wherein the bottom surface and the corresponding top surface of the bridge chip are provided with a plurality of bumps, and the top surface of the bridge chip is further provided with a plurality of first pads corresponding to the second pads; and the plurality of first pads are separately arranged on the top surface that is of the bridge chip and that is close to an outer edge;
bonding the bridge chip on the first surface of the first metal wire layer through a plurality of bumps on the bottom surface, so that the bottom surface of the bridge chip is electrically connected to the first metal wire layer;
filling around the bumps between the bottom surface of the bridge chip and the first metal wire layer by using a filler, connecting the first pad and the corresponding second pad through a lead, and providing a molding compound to mold the bridge chip, the conductive metal pillar and the lead, so as to form a bridge chip molding layer;
forming a second metal wire layer on a surface of the bridge chip molding layer, wherein the top surface of the bridge chip is electrically connected to the second metal wire layer through the bumps, the top surface of the bridge chip is electrically connected to the first metal wire layer through the lead, and the second metal wire layer is electrically connected to the first metal wire layer through the conductive metal pillar;
forming a chip structure molding layer on a surface of the second metal wire layer, wherein a chip in the chip structure molding layer is electrically connected to the second metal wire layer, so that the chip in the chip structure molding layer is electrically connected to the top surface of the bridge chip through the second metal wire layer, and the chip in the chip structure molding layer is electrically connected to the first metal wire layer through the second metal wire layer and the conductive metal pillar; and
removing the temporary carrier board and the plated layer, providing a plurality of solder balls on the first surface of the first metal wire layer after the plated layer is removed, bonding the chip structure formed above to the substrate through the solder balls, and then performing subsequent molding to complete packaging.

The step of forming a chip structure molding layer on a surface of the second metal wire layer specifically comprises the following steps: bonding a chip on the surface of the second metal wire layer through the bumps on the surface of the chip, filling around the bumps on the surface of the chip by using a filler, and molding the chip by using a molding compound to form the chip structure molding layer.

The present invention has been described with reference to the preferred embodiment, which is not intended to be limited thereto. Those skilled in the art can make possible variations and modifications to the present invention using the disclosed methods and technical contents without departing from the spirit and scope of the present invention; and therefore, any simple modifications, equivalent changes and modifications made to the above embodiments according to the technical spirit of the present invention without departing from the content of the technical solutions of the present invention shall fall within the protection scope of the technical solutions of the present invention

What is claimed is:

1. A bridge chip, wherein a top surface of the bridge chip is provided with a plurality of first pads and a chip connecting structure, the plurality of first pads are separately configured to connect a lead, the lead is configured to electrically connect the top surface of the bridge chip and a first metal wire layer that is connected to a bottom surface of the bridge chip, and the chip connecting structure is configured to bridge at least two chips.

2. The bridge chip according to claim 1, wherein the bottom surface of the bridge chip is configured to electrically connect to the first metal wire layer.

3. The bridge chip according to claim 1, wherein the bottom surface of the bridge chip is configured to be bonded to a first surface of the first metal wire layer by a plurality of bumps.

4. The bridge chip according to claim 3, wherein the top surface and the bottom surface of the bridge chip each have an independent device structure, and the top surface and the bottom surface of the bridge chip are electrically connected through the lead, the first metal wire layer and the bump.

5. The bridge chip according to claim 1, wherein the plurality of first pads are separately arranged on the top surface that is of the bridge chip and that is close to an outer edge.

6. The bridge chip according to claim 1, wherein the top surface of the bridge chip further has other device structures that are not limited to the function of interconnecting the chips.

7. A fan-out package structure comprising the bridge chip according to claim 1, comprising: a first metal wire layer, a bridge chip molding layer located on a first surface of the first metal wire layer, and a chip structure molding layer that is located on a surface of the bridge chip molding layer and that is electrically connected to the surface of the bridge chip molding layer;
wherein the bridge chip molding layer comprises a bridge chip, the first surface of the first metal wire layer is provided with a plurality of second pads corresponding to first pads, and the first pads and the corresponding second pads are connected through leads, so that a top surface of the bridge chip is electrically connected to the first metal wire layer.

8. The fan-out package structure according to claim 7, wherein a second metal wire layer is further provided between the bridge chip molding layer and the chip structure molding layer, the second metal wire layer is located on the surface of the bridge chip molding layer and electrically connected to a chip connecting structure of a bridge chip in the bridge chip molding layer, the chip structure molding layer is located on a surface of the second metal wire layer, and at least two chips of the chip structure molding layer are electrically connected to the second metal wire layer.

9. The fan-out package structure according to claim 7, wherein when a bottom surface of the bridge chip is bonded to a first surface of the first metal wire layer by a plurality of bumps, a curing adhesive is filled around the plurality of bumps between the bottom surface of the bridge chip and the first metal wire layer.

10. The fan-out package structure according to claim 7, wherein the lead is a copper wire or a gold wire.

11. The fan-out package structure according to claim 7, wherein the plurality of second pads are separately arranged around the bridge chip and corresponding to the first pads.

12. The fan-out package structure according to claim 8, wherein the bridge chip molding layer further comprises a conductive metal pillar and a molding compound encapsulating the bridge chip, the conductive metal pillar and the lead, the first metal wire layer is electrically connected to the second metal wire layer through the conductive metal pillar, and the chip connecting structure on the top surface of the bridge chip is electrically connected to the second metal wire layer through a plurality of bumps.

13. The fan-out package structure according to claim 8, wherein the chip structure molding layer comprises a first chip and a second chip separately electrically connected to the second metal wire layer and a molding compound encapsulating the first chip and the second chip, and the bridge chip is electrically connected to the first chip and the second chip separately through the second metal wire layer.

14. The fan-out package structure according to claim 7, further comprising a substrate and a heat dissipating lid, wherein the substrate is electrically connected to a second surface of the first metal wire layer.

15. The fan-out package structure according to claim 14, wherein the second surface of the first metal wire layer has a solder ball, a part of the solder ball located at a corresponding position of the bridge chip is electrically connected to the second pad, and the top surface of the bridge chip is electrically connected to the substrate through the lead, the second pad, and the part of the solder ball located at a corresponding position of the bridge chip.

16. A manufacturing method for a fan-out package structure, comprising the following steps:
providing a temporary carrier board, forming a plated layer on a surface of the temporary carrier board, and forming a first metal wire layer on a surface of the plated layer;
forming a bridge chip molding layer on a first surface of the first metal wire layer, wherein the bridge chip molding layer comprises a bridge chip, the bridge chip is located on the first surface of the first metal wire layer, a top surface of the bridge chip is provided with a plurality of first pads, the first surface of the first metal wire layer is provided with a plurality of second pads corresponding to first pads, and the first pads and the corresponding second pads are connected through leads, so that the top surface of the bridge chip is electrically connected to the first metal wire layer;
forming a chip structure molding layer on a surface of the bridge chip molding layer, wherein the chip structure molding layer is electrically connected to the bridge chip molding layer; and
removing the temporary carrier board and the plated layer.

17. The manufacturing method for a fan-out package structure according to claim 16, after removing the temporary carrier board and the plated layer, further comprising the following steps: mounting the structure formed above to a substrate, and additionally mounting a heat dissipating lid.

18. The manufacturing method for a fan-out package structure according to claim 17, wherein the step of mounting the structure formed above to a substrate specifically comprises: after removing the temporary carrier board and the plated layer, forming a solder ball on a second surface of the first metal wire layer, bonding the first metal wire layer on a surface of the substrate through the solder ball, electrically connecting the first metal wire layer and the surface of the substrate through the solder ball, and electrically connecting the top surface of the bridge chip and the substrate through the lead, the second pad, the first metal wire layer and the solder ball.

19. The manufacturing method for a fan-out package structure according to claim 16, wherein a chip structure molding layer is formed on the surface of the bridge chip molding layer, and the step of electrically connecting the chip structure molding layer and the bridge chip molding layer specifically comprises:
forming a second metal wire layer on the surface of the bridge chip molding layer, wherein a bridge chip of the bridge chip molding layer is electrically connected to the second metal wire layer; and
forming a chip structure molding layer on the surface of the second metal wire layer, wherein at least two chips of the chip structure molding layer are electrically connected to the second metal wire layer.

20. The manufacturing method for a fan-out package structure according to claim 16, wherein the plurality of first pads are separately arranged on the top surface that is of the bridge chip and that is close to an outer edge, and the plurality of second pads are separately arranged around the bridge chip and corresponding to the first pads.

21. The manufacturing method for a fan-out package structure according to claim 16, wherein the step of forming a bridge chip molding layer specifically comprises:
providing a bridge chip, wherein the bridge chip comprises a bottom surface and an opposite top surface, the bottom surface of the bridge chip is provided with a plurality of bumps, and the top surface of the bridge chip is provided with a plurality of first pads;
bonding the bridge chip on the first surface of the first metal wire layer through the plurality of bumps on the bottom surface, and forming a conductive metal pillar on the first surface of the first metal wire layer;
filling around the bumps between the bottom surface of the bridge chip and the first metal wire layer by using a filler, and connecting the first pad and the corresponding second pad through a lead, so that the top surface of the bridge chip is electrically connected to the first metal wire layer; and
providing a molding compound to mold the bridge chip, the conductive metal pillar and the lead to form the bridge chip molding layer.
